(19) United States
(12) Patent Application Publication
(10) Pub. No.: US 2014/0083458 A1
(43) Pub. Date: Mar. 27, 2014

(54) PHOTORESIST STRIPPING SOLUTION, STRIPPING SOLUTION RECYCLING SYSTEM AND OPERATING METHOD, AND METHOD FOR RECYCLING STRIPPING SOLUTION

(71) Applicants: Shinichirou Fuchigami, Kyoto (JP); Norio Yamaguchi, Ishikawa (JP); Masahiko Aikou, Osaka (JP); Koji Shimizu, Gifu (JP); Hiroyoshi Takezawa, Saitama (JP)

(72) Inventors: Shinichirou Fuchigami, Kyoto (JP); Norio Yamaguchi, Ishikawa (JP); Masahiko Aikou, Osaka (JP); Koji Shimizu, Gifu (JP); Hiroyoshi Takezawa, Saitama (JP)

(73) Assignee: PANASONIC CORPORATION, Osaka (JP)

(21) Appl. No.: 14/115,658

(22) PCT Filed: Oct. 6, 2011
(86) PCT No.: PCT/JP2011/073115

§ 371 Date: Nov. 5, 2013

(30) Foreign Application Priority Data
May 20, 2011 (JP) 2011-114207
May 20, 2011 (JP) 2011-114208

(51) Int. Cl. G03F 7/42

(52) U.S. Cl. CPC G03F 7/422
USPC 134/12; 510/176; 134/109

(57) ABSTRACT

Provided is a stripping solution recycling system using a photoresist stripping solution that strips a photoresist without damaging a Cu film or reducing the adhesiveness to a layer deposited on the Cu film, when a Cu film or Cu alloy film on a large-area substrate is wet-etched to make wiring or the like. The stripping solution recycling system has a resist stripping device for repeatedly using a stripping solution; a distillation and regeneration device for distilling the stripping solution in the waste tank; a component analyzer for investigating the composition ratio of the main agent and the polar solvent in the separated liquid; a preparation device for preparing the mixed solution; and a supply tank for storing the mixed solution.

### FIELD

The present invention relates to a photoresist stripping solution. More particularly, the present invention relates to a photoresist stripping solution suitably used for producing Cu or Cu alloy wiring substrates of flat panel displays (FPDs) such as liquid crystal displays and organic EL displays, a stripping solution recycling system and operating method, and a method for recycling a stripping solution.

### BACKGROUND

In IC, LSI, or the like, finer multilayer wiring circuits have been developed with higher integration of semiconductor devices and reduction in chip size, and there have been issues of signal delay and the like associated with resistance (wiring resistance) and wiring capacity of metal films used in semiconductor devices. For this reason, copper (Cu) with less resistance than aluminum (Al) has been used in order to reduce wiring resistance.

Al also has been conventionally employed as a wiring material in FPDs such as liquid crystal displays. As in semiconductor devices, however, it has been required to reduce wiring resistance corresponding to large-sized substrates, higher resolution, and organic EL these years, and thus an attempt has been made to use a Cu or Cu alloy and the like with less resistance than Al as wiring materials.

Cu is more corrosive in aqueous solutions due to a weaker protective property of an oxide film generated on its surface than Al. Accordingly, there has been such a problem that wiring patterns cannot be stably formed. In manufacture of semiconductors, corrosion is prevented by dry process using plasma. FPDs, however, have a larger substrate than semiconductors, which makes application of dry process using plasma difficult. For this reason, development of wiring formation using wet etching has been absolutely necessary.

The problem in using Cu as a wiring material is corrosion of a Cu film surface by wet etching as described above. As well known, in photolithography by wet etching, a desired wiring pattern can be obtained by forming a wiring pattern with a resist on a Cu film formed on a base material, removing an unnecessary part of the Cu film with an etchant for dissolving Cu, and finally removing the resist.

The Cu film here is corroded in the final step of stripping the resist film. In this step, the resist attached to the Cu film surface is removed and accordingly the Cu film surface is directly exposed to a stripping solution. In particular, the stripping solution for resists is alkaline and also contains water. For this reason, the Cu film is easily corroded. Accordingly, a photoresist stripping solution has been developed which achieves stripping of a photoresist and prevention of corrosion of a Cu film in a well-balanced manner. As a main procedure, a corrosion inhibitor for a Cu film is mixed in the stripping solution.

Patent Literature 1 has disclosed a photoresist stripping solution including (a) 10% to 65% by weight of a nitrogen-containing organic hydroxy compound, (b) 10% to 60% by weight of a water soluble organic solvent, (c) 5% to 50% by weight of water, (d) 0.1% to 10% by weight of a benzotriazole-based compound as an anti-corrosive agent, in which amines having an acid dissociation constant (pKa) of 7.5 to 13 in aqueous solutions at 25° C. are preferred as the (a) nitrogen-containing organic hydroxy compound.

The photoresist stripping solution having such composition, however, is strong alkaline with a pH of 10 or more. Accordingly, copper wiring produces HCuO₂⁻ and CuO₂⁻ ions due to oxygen dissolved in solutions, causing easy dissolution, i.e., corrosion. The (d) benzotriazole-based compound as an anti-corrosive agent cannot produce a polymer film having high degree of polymerization in strong alkali solutions and thus has a weak anti-corrosion property. For this reason, the amount of the benzotriazole-based compound added has to be increased and thus there has been a risk that excessive of the benzotriazole-based compound added remains on Cu film wiring and is left as an undesired substance.

Patent Literature 2 has disclosed a photoresist stripping solution including (a) 5% to 45% by weight of a primary or secondary alkanolamine, (b) 50% to 94.95% by weight of a polar organic solvent and water, (c) 0.05% to 10% by weight of at least one heterocyclic compound selected from the group consisting of maltol, uracil, 4-hydroxy-6-methyl-2-pyrone, and the like. Even in the case of such composition, the photoresist stripping solution is strong alkaline with a pH of 10 or more and easily corrodes copper wiring. Accordingly, there has been a risk that excessive of the anti-corrosive agent (c) added remains on Cu wiring and is left as an undesired substance.

Patent Literature 3 has proposed a method for producing semiconductor devices, in which a copper wiring pattern is formed on a substrate and subsequently the copper wiring pattern is washed with an aqueous solution containing 2×10⁻⁶ to 10⁻¹ mol/dm³ of benzotriazole.

Furthermore, various solutions including a stripping solution have been used in large amounts in wet etching technique. They may cause a high risk of environmental pollution when directly discarded. They are also relatively expensive materials. Accordingly, the used stripping solution and the like are preferably recycled and repeatedly used while being regenerated.

In such a viewpoint, Patent Literature 4 has disclosed a stripping solution including polyhydric alcohol, alkanolamine, water, glycol ether, and an anti-corrosive agent. In particular, from a viewpoint of recycling, it is desirable to include 30% by mass or less of water and 60% by mass or more of glycol ether as a material to be mainly regenerated.

In order to always keep the concentration of a stripping solution used in large amounts within a given range, Patent Literatures 5 to 7 have disclosed techniques of always keeping constant the concentration of a stripping solution by measuring the component concentration of the repeatedly used stripping solution with an absorption spectrometer, and supplying deficient components in real time.

### CITATION LIST

### Patent Literature

Patent Literature 1: Japanese Patent No. 3514435
Patent Literature 2: Japanese Patent Application Laid-Open No. 2008-216296
Patent Literature 3: Japanese Patent No. 3306598
Patent Literature 4: Japanese Patent Application Laid-Open No. 2007-114519
Patent Literature 5: Japanese Patent No. 2602179
Patent Literature 6: Japanese Patent No. 3093975
Patent Literature 7: Japanese Patent No. 3126690

### SUMMARY

### Technical Problem

In Patent Literature 1, etching of Cu has been performed by dry etching and evaluated. It has been known that an etchant for Cu is different from that for Al. In particular, with an oxidizing etching solution for wet-etching Cu, a resist layer has been altered and hardly stripped. Specifically, the photoresist stripping solution disclosed in Patent Literature 1 cannot be simply applied as a photoresist stripping solution used in the step of wet-etching Cu or a Cu alloy.

Patent Literature 2 has considered this point and disclosed a photoresist stripping solution used in wet-etching Cu or a Cu alloy on a large-area substrate. A primary or secondary alkanolamine used as a main agent of the stripping solution, however, is strong alkaline, decreasing the effect of a heterocyclic compound added as a corrosion inhibitor. Accordingly, the proportion of the heterocyclic compound has been large such as 0.05 to 10 wt %.

What has not been discussed in Patent Literature 2 is that such heterocyclic compounds added as corrosion inhibitors form insoluble compounds between themselves and a Cu film to prevent corrosion but decrease the adhesiveness to a layer formed on the Cu film at the same time. That is, 0.05 to 10 wt % of the corrosion inhibitor has caused a problem of decreased adhesiveness to the film formed on the Cu film.

Patent Literature 3 has disclosed that BTA (benzotriazole) forms an insoluble compound between itself and a Cu film in order to prevent corrosion when the Cu film is brought into contact with a washing agent during a washing process for stripping a photoresist on the Cu film. It is, however, basically assumed that the Cu film is processed by dry etching. The adhesiveness to the subsequent layer formed on the Cu film also has not been taken into consideration as in Patent Literature 2.

In addition, the following problems have occurred from a viewpoint of recycling of the stripping solution. Among materials constituting the stripping solution, an amine-based material, a solvent, and a corrosion inhibitor have a close boiling point, and thus separation of these is not easy. That is, the amine-based material, the solvent, and the corrosion inhibitor are collectively separated. A separated liquid which is collectively separated is examined for its composition ratio of materials and deficiencies of the materials are added for regeneration.

Considering the adhesiveness to the film formed on the Cu film here as described above, the corrosion inhibitor can be added only in a trace amount. In that case, it is difficult to examine the content of the corrosion inhibitor in the liquid separated from a waste of the stripping solution by distillation or the like. This is because, in addition to low content, the corrosion inhibitor has a close boiling point to the amine-based material and the solvent so that it cannot be distinguished nor discriminated from others.

When the stripping solution is repeatedly regenerated (recycled) in such circumstance, the corrosion inhibitor is concentrated therein even in a trace amount. The corrosion inhibitor exhibits a corrosion prevention effect in a trace amount. That is, it forms passivation on the Cu film. Accordingly, even small amount of the corrosion inhibitor concentrated certainly has an effect on the adhesiveness to the film formed on the Cu film. As a result, the use of a regenerated stripping solution may cause problems of pinholes suddenly formed in the film formed on the Cu film and stripping of the film from the Cu film at a certain point.

Patent Literatures 5 to 7 have disclosed inventions for keeping constant a component concentration of a stripping solution which is repeatedly used. They have not disclosed that a waste of the stripping solution is recycled. However, since they have disclosed that the waste includes an amine as a main agent, a solvent, and water, recycling of the waste of the stripping solution, which has such composition, may be presumed in combination of conventional techniques. Patent Literatures 5 to 7, however, have not disclosed anything about removal of a resist film formed on the Cu film. Accordingly, they have not intended to technically solve how to recycle the stripping solution for removing the resist film on the Cu film.

The present invention provides a photoresist stripping solution for stripping a photoresist which is altered and hardly stripped due to exposure to light without damaging a Cu film nor reducing the adhesion to a film formed on a Cu film when a Cu or Cu alloy layer on a large-area substrate is wet-etched to make wiring or the like, a system for recycling the stripping solution and a method for operating the same, and a method for recycling the stripping solution.

### Solution to Problem

In order to solve the above-mentioned problems, it is required to use a corrosion inhibitor that can be easily separated from constituents of a stripping solution. As a result of intensive studies, the present inventors have completed the present invention by confirming that combination of a photoresist itself exposed to light and stripped with a stripping solution and the stripping solution low corrosive to a Cu film can cause dissolution of a resist film without corrosion of the Cu film.

The photoresist stripping solution of the present invention is characterized by using a tertiary amine as a main agent and a resist composition which may serve as a corrosion inhibitor. In addition, the present invention does not include a corrosion inhibitor which is represented by a benzotriazole-based compound and added in a trace amount.

More specifically, the photoresist stripping solution of the present invention is characterized by including 1% to 9% by mass of a tertiary alkanolamine, 10% to 70% by mass of a polar solvent, 10% to 40% by mass of water, and 3000 ppm or less of a resist composition.

The above photoresist stripping solution is also characterized in that the tertiary alkanolamine is N-methyldiethanolamine (MDEA).

The above photoresist stripping solution is also characterized in that the polar solvent is a mixed solvent of diethylene glycol monobutyl ether (BDG) and propylene glycol (PG).

The above photoresist stripping solution is also characterized in that the resist composition is originated from an exposed positive photoresist.

The above photoresist stripping solution is also characterized in that the stripping solution is one for stripping a positive photoresist coated on a Cu film.

The stripping solution recycling system of the present invention regenerates and uses a stripping solution for stripping an exposed positive resist film which is formed on a Cu film, the stripping solution recycling system characterized by including:

a stripping solution tank for storing therein a stripping solution comprising a resist composition and a mixed solution comprising a main agent, a polar solvent, and water;

removing means for removing an exposed positive resist film on a workpiece repeatedly using the stripping solution in the stripping solution tank;

a supply tube for supplying the mixed solution to the stripping solution tank;

a discharge tube for discharging part of the stripping solution in the stripping solution tank;

a resist stripping device for discharging part of the stripping solution from the discharge tube when a resist concentration of the stripping solution reaches a given value and receiving supply of a fresh stripping solution from the supply tube;

a waste tank for storing therein the discharged stripping solution, the waste tank being connected to the discharge tube;

a distillation and regeneration device for distilling the discharged stripping solution in the waste tank to obtain a separated liquid containing the main agent and the polar solvent;

a component analyzer for investigating a composition ratio of the main agent and the polar solvent in the separated liquid;

a preparation device for preparing a regenerated mixed solution by adding deficiencies of the main agent, the polar solvent, and water to show a predetermined proportion of the main agent, the polar solvent, and the water in the separated liquid; and

a supply tank for storing therein the regenerated mixed solution.

The stripping solution recycling system of the present invention is characterized in that the stripping solution includes 1% to 9% by mass of a tertiary alkanolamine, 10% to 70% by mass of the polar solvent, 10% to 40% by mass of water, and 100 ppm to 3000 ppm of the resist composition.

The method for operating the stripping solution recycling system of the present invention is characterized by including the steps of:

determining the resist concentration of a stripping solution in the stripping solution tank of the resist stripping device;

withdrawing part of the storage stripping solution when the resist concentration reaches a given value;

adding a mixed solution to the stripping solution tank from the supply tank until the resist concentration reaches a given minimum value;

obtaining a separated liquid containing the main agent and the polar solvent by distilling the withdrawn part of the stripping solution in the distillation and regeneration device;

investigating the component ratio in the separated liquid;

preparing a regenerated mixed solution by adding deficiencies of the main agent, the polar solvent, and water to show a predetermined proportion of the main agent, the polar solvent, and the water in the separated liquid; and

storing the regenerated mixed solution in the supply tank.

The method for recycling a stripping solution of the present invention is a method for recycling a photoresist stripping solution containing 1% to 9% by mass of a tertiary alkanolamine, 10% to 70% by mass of a polar solvent, 10% to 40% by mass of water, and 3000 ppm or less of a resist composition, the method including the steps of:

introducing the stripping solution into a process vessel where a stripping process is conducted;

conducting the stripping process;

monitoring a resist concentration in a stripping process solution;

stopping the stripping process when a concentration of the resist composition in the stripping solution exceeds a given value, and withdrawing part of the stripping solution;

extracting a separated liquid containing the tertiary alkanolamine and the polar solvent by distilling the withdrawn stripping solution;

regenerating the stripping solution by adding components deficient as the stripping solution to the separated liquid; and

introducing the regenerated stripping solution into the process vessel again.

### Advantageous Effects of Invention

The stripping solution recycling system of the present invention is used for the resist stripping solution comprising the tertiary alkanolamine, the polar solvent, and the water, where the resist composition is used as a corrosion inhibitor for the Cu film, and accordingly the separated liquid containing the tertiary alkanolamine and the polar solvent, the water, and the resist composition can be completely separated from each other. That is, the regenerated tertiary alkanolamine and polar solvent are free from trace additives such as a corrosion inhibitor for the Cu film. Therefore, trace components are never concentrated even though the stripping solution is repeatedly regenerated, so that the stripping solution for the resist formed on the Cu film can be stably recycled.

In addition, only the tertiary alkanolamine, the polar solvent, and the water are additionally supplied into the process vessel (process tank) while a given amount of the used stripping solution is always left therein, thereby maintaining the stripping solution having a corrosion prevention function for the Cu film.

### BRIEF DESCRIPTION OF DRAWINGS

FIG. 1 is a diagram illustrating the configuration of a recycling system of the present invention.

FIG. 2 is a diagram illustrating the configuration of a stripping solution device.

FIG. 3 is a diagram illustrating the configuration of a distillation and regeneration device.

FIG. 4 is a diagram illustrating the configuration of a preparation device and a raw material tank.

FIG. 5 is a chart illustrating an operational flow of the recycling system of the present invention.

FIG. 6 is a chart illustrating an operational flow of the distillation and regeneration device in the recycling system of the present invention.

FIG. 7 illustrates change in concentration of the resist composition and change in amount of the stripping solution due to exchange of the stripping solution in the stripping solution tank inside the stripping device.

FIG. 8 is a figure illustrating the relationship between the concentration of the resist composition in the stripping solution and the defect rate of products.

FIG. 9 is a chart illustrating a flow of the method for recycling the stripping solution.

FIG. 10 is a diagram illustrating the configuration of Example where a substrate washing line is provided in the recycling system of the present invention.

### DESCRIPTION OF EMBODIMENTS

While the present invention will be described below with reference to the drawings and Examples, the embodiments can be modified without departing from the spirit of the present invention.

### First Embodiment

A photoresist stripping solution used for the present invention includes 1% to 9% by mass of a tertiary alkanolamine, 10% to 70% by mass of a polar solvent, 10% to 40% by mass of water, and 3000 ppm or less of a resist composition. A mixture of the tertiary alkanolamine, the polar solvent, and the water is referred to as a mixed solution for convenience in this specification and the claims. The tertiary alkanolamine is also referred to as an amine or a tertiary amine.

Specifically, the following can be suitably utilized as the tertiary alkanolamine; triethanolamine, N,N-dimethylethanolamine, N,N-diethylethanolamine, N,N-dibutylethanolamine, N-methylethanolamine, N-ethylethanolamine, N-butylethanolamine, N-methyldiethanolamine, or the like. They may be used in a mixture of two or more kinds thereof.

Any organic solvents having an affinity for water can be used as the polar solvent. It is more suitable for the organic solvents to easily mix with the above tertiary alkanolamines.

Examples of such water-soluble organic solvents include sulfoxides such as dimethyl sulfoxide; sulfones such as dimethyl sulfone, diethyl sulfone, bis(2-hydroxyethyl)sulfone, and tetramethylene sulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; and polyhydric alcohols such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monoalkyl ethers (alkyl is a lower alkyl group with 1 to 6 carbon atoms) such as diethylene glycol monomethyl ether, diethylene glycol monoethyl ether, diethylene glycol monopropyl ether, and diethylene glycol monobutyl ether, and their derivatives. Among these, at least one selected from dimethyl sulfoxide, N-methyl-2-pyrrolidone, and diethylene glycol monobutyl ether is preferably used in terms of a better stripping property and anti-corrosion property to a substrate, and the like. Among them, diethylene glycol monobutyl ether and N-methyl-2-pyrrolidone are particularly preferred. These components may be used in a mixture of two or more kinds thereof.

Although the water is preferably pure water, impurities may be contained therein within the range of industrial use. Accordingly, it is not necessary to use pure water passed through a reverse osmosis (RO) film. This is because when several μm or more of wiring is formed, a few impurities may be acceptable in some cases.

The stripping solution used in the present invention may include, in addition to the mixed solution (tertiary alkanolamine, polar solvent, and water), 3000 ppm or less of the resist composition. The resist composition is originated form the photoresist which the stripping solution of the present invention strips. More specifically, it is the resist composition that is exposed to light and an (acidic) etchant in the step of photolithography and stripped from the Cu film surface by the stripping solution.

Accordingly, the “resist composition” in this specification may include modified components of the photoresist before exposure to light. In other words, the resist composition may include components that are not included in the photoresist before exposure to light, as long as they are components included in the exposed photoresist or dissolved out of the exposed photoresist into the mixed solution, or components that are modified by association with the stripping solution and dissolved out.

The present inventor has completed the present invention by confirming that, when the photoresist which is coated on the Cu film and exposed to light is dissolved by the mixed solution (tertiary alkanolamine, polar solvent, and water), the corrosion of the Cu film to the level causing substantially no problem can be suppressed and also the solubility of the resist can be maintained. This reason is not clear but considered as follows as one explanation.

The positive photoresist is a mixture of a resin soluble in an alkali solution and a photosensitive agent, and it is considered that the photosensitive agent protects soluble points of the resin. A novolak resin is often used as the resin. Diazonaphthoquinone (DNQ) is often used as the photosensitive agent for the positive photoresist. When exposed to light, this DNQ is changed into indene ketene. When indene ketene comes into contact with water, it is changed into indene carboxylic acid through a hydrolysis reaction.

Indene carboxylic acid is dissolved out into in an alkali solution because it is soluble therein. As a result, the soluble points of the resin are exposed to an alkali solution and the photoresist is stripped. It is supposed here that attachment of this indene carboxylic acid to the Cu film surface prevents the Cu film from being corroded by the mixed solution (tertiary alkanolamine, polar solvent, and water). Since this indene carboxylic acid has a melting point of 200° C. or more, separation of the stripping solution from the mixed solution is very easy. Accordingly, the resist composition is preferably originated from the positive photoresist.

The stripping solution including these components does not inhibit dissolution of the exposed resist itself. As described below in Examples, it is considered that this occurs because these components are basically dissolved out of the exposed resist film and accordingly do not cause reattachment or rebinding to dissolved parts of the film.

When the stripping solution of the present invention is used for the Cu film having the exposed photoresist formed thereon, the stripping solution to be first introduced may not contain the resist composition. This is because the resist composition can be obtained from the exposed resist.

Although not clear, corrosion of the Cu film surface may be prevented by the resist composition in the stripping solution of the present invention. Accordingly, the stripping solution at the beginning of use, even though not including the resist composition, is supplied with the resist composition from the exposed photoresist on the Cu film. In other words, however, the repeated use of the stripping solution increases the concentration of the resist composition therein. Since the resist composition also includes the resin constituting the resist, the increase in concentration of the resist composition also leads to increase in debris (fragments of the resist film). Larger amount of the resist composition remaining on the Cu film surface results in lower adhesiveness thereof to the film formed on the Cu film.

That is, there is an upper limit on the concentration of the resist composition in order to effectively utilize the stripping solution. Regarding the stripping solution used in the present invention, the stripping solution to be repeatedly used preferably includes 3000 ppm or less of the resist composition. This is because the resist composition of this concentration or more generates poor adhesive parts such as pinholes in the film formed on the Cu film. In other words, the stripping solution used in the present invention can be repeatedly used without being regenerated until the concentration of the resist composition rises from zero to 3000 ppm.

Since it is supposed that a corrosion inhibitor is obtained from the resist composition in the stripping solution of the present invention, the corrosion of the Cu film surface is suppressed. However, when other components in the stripping solution are highly corrosive such that the Cu film surface cannot be protected with the corrosion inhibitor, the Cu film surface is corroded. Accordingly, the proportion of the tertiary alkanolamine, the polar solvent, and the water in the stripping solution used in the present invention needs to be such that the stripping solution is alkaline to dissolve the exposed resist, and corrosive such that the Cu film substantially remains in the presence of the resist composition. The “Cu film substantially remains” here means that the Cu film remains to the extent not causing any problem as a product, even if the exposed resist on the Cu film is removed with the stripping solution.

For this reason, the amount of the tertiary alkanolamine blended in the photoresist stripping solution of the present invention is 1% to 9% by mass, more preferably 2% to 7% by mass, and most preferably 4% to 6% by mass with respect to the total amount of the stripping solution. This is because 9% by mass or more of the tertiary alkanolamine included causes the corrosion on the Cu film even if the resist composition is included. Furthermore, 1% by mass or less makes it impossible to strip the photoresist.

As also illustrated below in Examples, the pH of the tertiary alkanolamine is not so different from that of primary and secondary alkanolamines. Regarding an acid dissociation constant (pKa), however, MEA (monoethanolamine), being primary alkanolamine, has a pKa of 9.55, whereas MDEA (N-methyldiethanolamine), being tertiary alkanolamine, has a pKa of 8.52. That is, MDEA is weaker alkaline. Accordingly, the tertiary alkanolamine is considered to be less corrosive to the Cu film surface.

The following point of view is also possible from a different angle. A hydroxyl group still remains on nitrogen in primary and secondary amines. This hydroxyl group is supposed to easily trap the indene carboxylic acid mentioned above. For a tertiary amine, however, the hydroxyl group bonded to nitrogen is replaced by another functional group, and does not inhibit movement of the indene carboxylic acid. Accordingly, in the primary and secondary amines, the indene carboxylic acid generated from the resist film cannot bind to the Cu film surface and thus causes corrosion of the Cu film surface. On the other hand, in the presence of the tertiary amine, the indene carboxylic acid produced in the solution forms a protective layer on the Cu film without being inhibited by the tertiary amine.

Both reactions may also occur at the same time. In any case, the combination of the tertiary alkanolamine, the polar solvent, and the water hardly corrodes the Cu film when removing the resist film from the Cu film having the exposed resist film formed thereon.

The ratio of the polar solvent is suitably 10% to 70% by mass, more preferably 30% to 70% by mass, and most preferably 50% to 70% by mass with respect to the total amount of the stripping solution. Furthermore, the ratio of the water is suitably 10% to 40% by mass, more preferably 20% to 40% by mass, and most preferably 30% to 40% by mass. In addition, the polar solvent and the water may be adjusted within the above composition range at the temperature of use so as to show a suitable viscosity of the stripping solution which is the mixed solution with the tertiary alkanolamine.

The reaction of the stripping solution with the resin or the photosensitive agent in the photoresist is closely related to the temperature. Accordingly, temperature control when using the stripping solution is strictly carried out. The temperature when using the stripping solution of the present invention and the workpiece is suitably within the range of from 35° C. to 45° C., and more suitably within the range of from 38° C. to 42° C. It is desirable to process both the workpiece and the stripping solution at the same temperature. Since the base material of FPD is very large, the space where the stripping solution is used can be large. The temperature range of from 35 to 45° C. allows the chemical reactions to stably proceed in such a space and furthermore the temperature control to be maintained without large energy. Specific examples of the resist stripping solution used in the present invention will be described below in Examples.

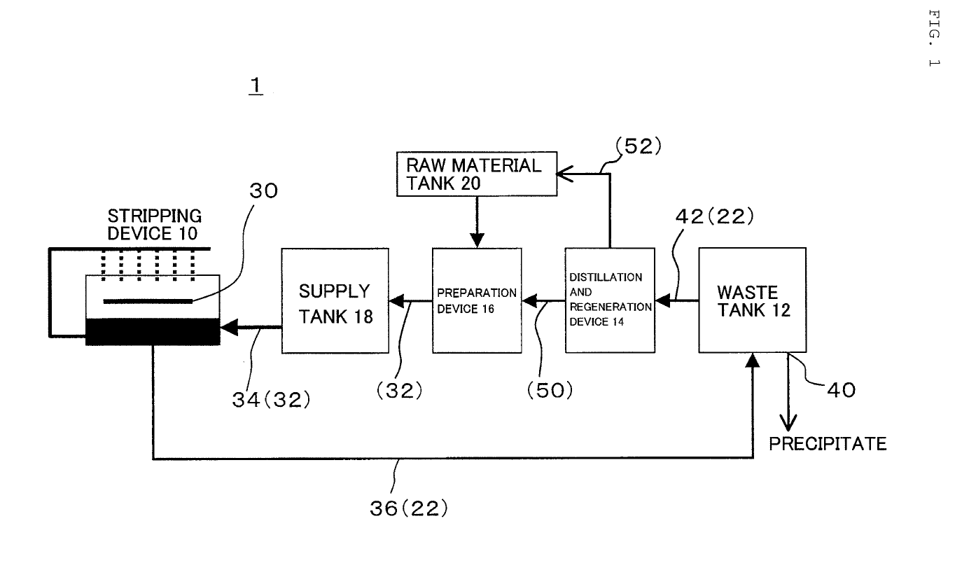

Next, the stripping solution recycling system of the present invention will be described. FIG. 1 is a diagram illustrating the configuration of the stripping solution recycling system of the present invention. A stripping solution recycling system 1 of the present invention includes a resist stripping device (also, simply referred to as a “stripping device”) 10, a waste tank 12, a distillation and regeneration device 14, a preparation device 16, a supply tank 18, and a raw material tank 20. In FIG. 1, parenthesized numbers were used to indicate the stripping solution and the like flowing through the tubes.

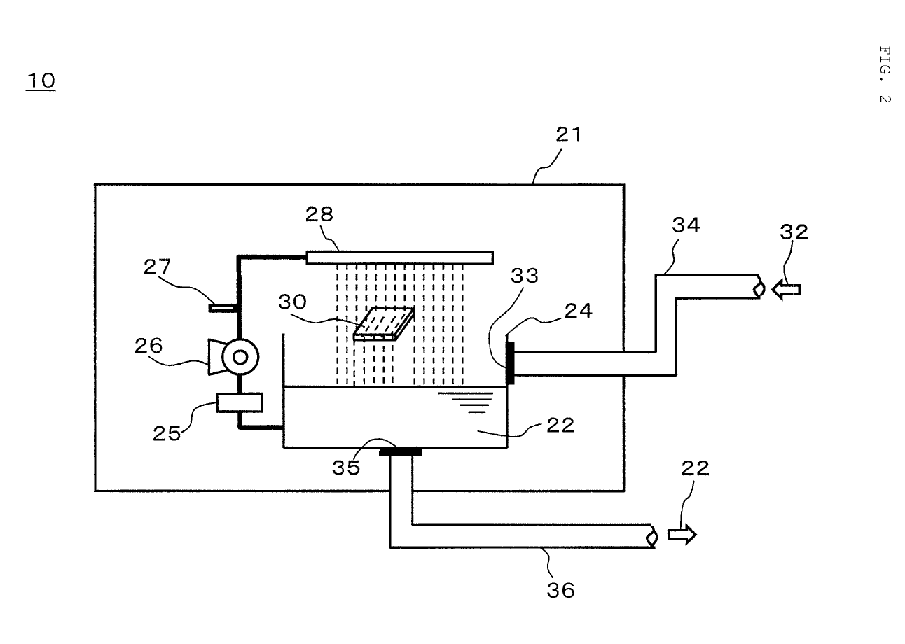

With reference to FIG. 2, the resist stripping device 10 includes a stripping solution tank 24 for storing therein a stripping solution 22, a pump 26 for pumping up the stripping solution 22 from the stripping solution tank 24, and a shower 28 for allowing the stripping solution 22 to fall down, in a chamber 21 capable of controlling temperature and humidity adjustment. In addition, suitable conveyance means (not shown) is provided to bring a workpiece 30 having a resist to be removed on its surface into the chamber 21 and take it out after the process with the stripping solution 22.

For the temperature and humidity adjustment in the chamber 21, a heat exchanger capable of heating and cooling may be disposed in the chamber 21. It is, however, easier to supply nitrogen gas with adjusted temperature and humidity into the chamber 21 at a constant flow rate. This is because large plants are often provided with facilities for stably supplying such nitrogen gas.

The stripping solution 22 is the stripping solution used in the present invention as mentioned above. Specifically, the photoresist stripping solution includes 1% to 9% by mass of the tertiary alkanolamine, 10% to 70% by mass of the polar solvent, 10% to 40% by mass of the water, and 3000 ppm or less of the resist composition. As clarified in Examples described below, it is considered that this stripping solution may obtain a corrosion prevention effect on the Cu film surface through the exposed resist film. Accordingly, it is only necessary to supply the tertiary alkanolamine, the polar solvent, and the water to the stripping solution tank 24. This is because the resist composition from the exposed resist film is obtained from the workpiece. In this specification, a mixture of the tertiary alkanolamine, the polar solvent, and the water at a given amount was referred to as a mixed solution 32.

The stripping solution 22 is stored in the stripping solution tank 24. The stripping solution tank 24 has a mixed-solution supply port 33 for supplying the mixed solution 32 and a discharge port 35 for discharging the used stripping solution 22 as a waste. The mixed-solution supply port 33 is the opening end of a supply tube 34 in communication with the supply tank 18 and the discharge port 35 is the opening end of a discharge tube 36 in communication with the waste tank 12. Moreover, the stripping solution tank 24 is connected to the pump 26 for pumping out the stripping solution 22. A filter 25 may be disposed upstream of the pump 26.

The pump 26 allows the stripping solution 22 to be delivered to the shower 28. The stripping solution 22 is released from the shower 28 and showered down on the workpiece 30 to remove the resist from the substrate. The stripping solution 22 containing the removed resist is brought together in the stripping solution tank 24 again. In this manner, the stripping solution 22 in the stripping solution tank 24 is repeatedly used.

The method for removing the resist with the stripping solution 22 is not limited by the above description. For example, a method of spraying the stripping solution 22 on the workpiece 30, a method of dipping the workpiece 30 into a shallow tray where the stripping solution 22 is always overflowed, or other methods may be used. The stripping solution tank 24, the pump 26, and the shower 28 compose the removing member in the stripping device 10.

A heater, not shown, is disposed in the stripping solution tank 24. The heater is for keeping the temperature of the stripping solution 22 constant. Since the stripping solution 22 removes the exposed resist by dissolving it, the temperature of the stripping solution 22 needs to be strictly controlled. This is because the temperature of the solution has an effect on the dissolution rate. The temperature of the stripping solution 22 used in the present invention is suitably from 35° C. to 45° C., and more suitably from 38° C. to 42° C.

The temperature of the stripping solution 22 desirably corresponds with the temperature inside the chamber 21. More desirably, the workpiece 30 is also heated to the same temperature as the stripping solution 22 before brought into the chamber 21. This is because temperature change of the stripping solution 22 repeatedly used can be reduced.

Conventional photoresist stripping solutions are often used at from 60° C. to 80° C. In the present invention, however, the stripping solution 22 is used at a relatively low temperature. The decreased temperature in using the stripping solution 22 provides an effect of achieving the same temperature of the inside of the chamber 21, the stripping solution 22, and the workpiece 30 at low cost as well as an effect of suppressing evaporation of the water in the stripping solution 22. Accordingly, the use of the stripping solution 22 at a temperature of 50° C. or lower causes the water in the stripping solution 22 to hardly evaporate and can reduce change in component ratio in the stripping solution 22.

In the stripping solution 22 repeatedly used, the concentration of the resist composition increases. When the concentration of the resist composition reaches a given value, part of the stripping solution 22 is discharged as a waste and a fresh mixed solution 32 is additionally poured. Accordingly, it is desirable to provide means (resist concentration detection means 27) for detecting the resist concentration in the stripping solution 22. The “fresh mixed solution 32” additionally poured here may be a regenerated mixed solution which is recycled in the recycling system of the present invention, or may be a mixed solution prepared with components which are not regenerated in the recycling system of the present invention. It also may be a mixed solution prepared by mixing these.

A method for detecting the resist concentration in the stripping solution 22 is not particularly limited. However, since the mixed solution 32 used in the present invention is transparent and colorless, the simplest method is to confirm the tone of wine color due to the dissolved resist composition with the naked eye. More specifically, provided is the method where a transparent part is provided on the pipe downstream of the pump 26, irradiated with a given intensity of light from behind, and then compared with color samples produced beforehand.

Referring to FIG. 1 again, the stripping solution 22 which is repeatedly used in the stripping device 10 needs to be exchanged when the concentration of the resist composition increases to over 3000 ppm. Part of the used stripping solution 22 is transferred to the waste tank 12 from the discharge port 35 (see FIG. 2) through the discharge tube 36. The waste tank 12 is a container for temporarily storing therein the waste of the stripping solution 22 for recycling.

The structure of the waste tank 12 is not particularly limited. Since the stripping solution 22 contains water and is alkaline due to the tertiary alkanolamine used as a main agent, the waste tank 12 preferably has an inner surface made of a corrosion-resistance material. The waste of the stripping solution 22 may contain the resist composition in a solid form, and a precipitate is generated by settling the waste of the stripping solution 22. It is preferred to provide a discharge port 40 for discharging this precipitate. This precipitate is separately discarded. A transfer pipe 42 is also provided for transferring the waste in the waste tank 12 to the distillation and regeneration device 14.

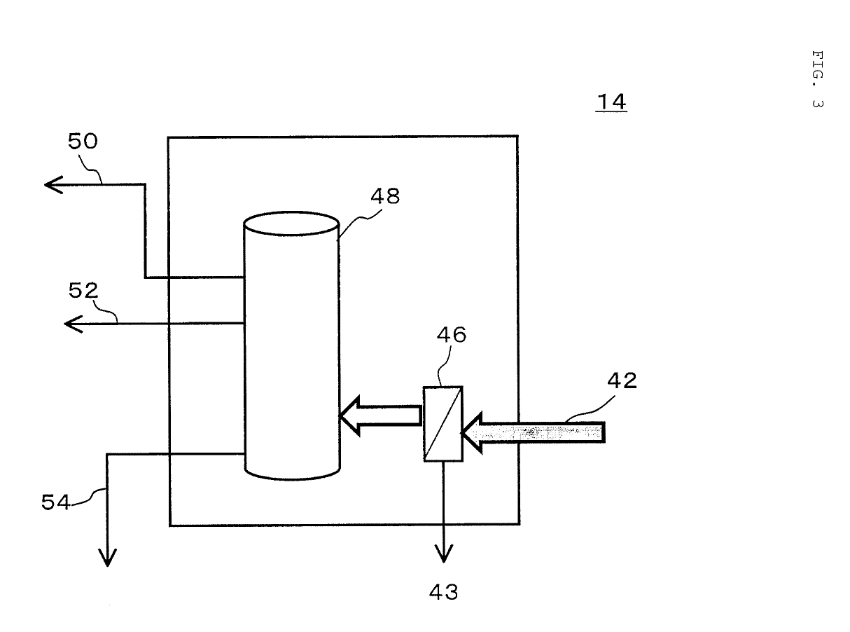

FIG. 3 illustrates the configuration of the distillation and regeneration device 14. The distillation and regeneration device 14 includes a filter 46 and a distillation column 48. The filter 46 is for removing fine solid content from the waste transferred from the waste tank 12. Since the waste also contains a resin component included in the resist, the fine solid content and the resin component may be removed through a micro filtration (MF) film, an ultra-filtration (UF) film, or the like. Components filtered out through the filter 46 at the primary side are discarded as an unnecessary portion 43.

The distillation column 48 separates the tertiary alkanolamine used as a main agent and the polar solvent from the waste. This is because they are too large in amount to be directly discarded and are also expensive among the components of the stripping solution 22. The stripping solution used in the present invention includes the main agent, the polar solvent, and the water (the mixed solution 32), and the resist composition. Thus, when the main agent and the polar solvent are considered as one unit (hereinafter, referred to as a “separated liquid 50”), separation is relatively easy. This is because the resist composition has a high melting point and thus remains as a residue when the separated liquid 50 and the water are separated. Although single distillation column 48 is described in FIG. 3, a plurality of distillation columns 48 may be provided depending on the scale of process.

The main agent and the polar solvent often have a close boiling point and accurate separation of these is not easy. In terms of recycling of the stripping solution, however, handling of these together does not particularly cause any problem. It is then decided to obtain the separated liquid 50 containing the main agent and the polar solvent as a mixture, the water 52, and a residue 54 through the distillation column 48. The residue 54 includes components from the positive resist and is thus separately discarded like the precipitate in the waste tank 12 and the unnecessary portion 43.

The separated water 52 is confirmed to be free from components of the separated liquid 50 and subsequently delivered to and stored in the raw material tank 20. The separated water 52 may be directly utilized in other applications. When the separated water 52 still contains components of the separated liquid 50, it is delivered to the distillation column 48 again for distillation.

Referring to FIG. 1 again, the separated liquid 50 obtained from the distillation and regeneration device 14 is delivered to the preparation device 16.

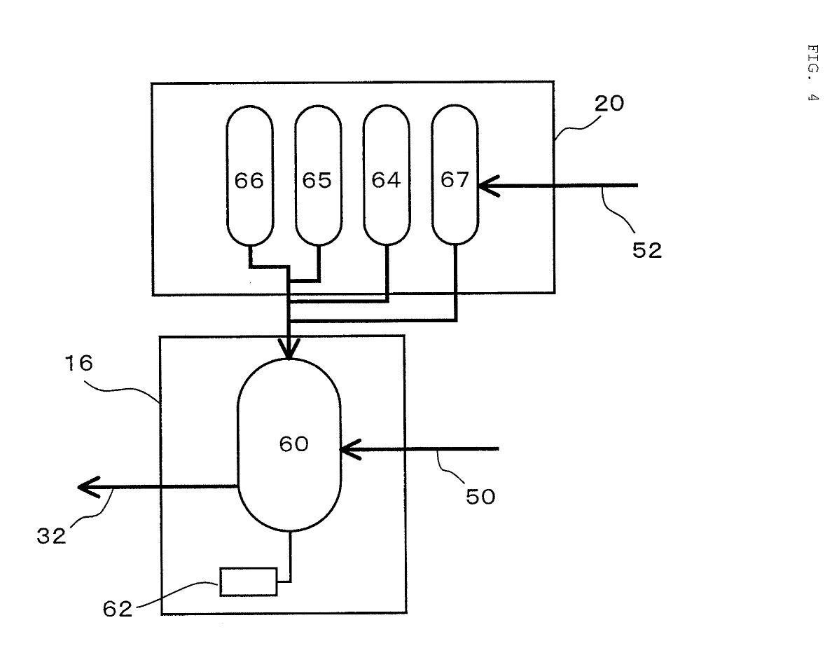

FIG. 4 illustrates the configuration of the preparation device 16 and the raw material tank 20. The preparation device 16 includes a preparation tank 60 and a component analyzer 62. The raw material tank 20 includes a tank 64 for the tertiary alkanolamine used as a main agent, a tank 65 for a (first) polar solvent, a tank 66 for a (second) polar solvent, and a tank 67 for water. Although two tanks for polar solvents are illustrated here, one tank for a polar solvent or three or more tanks for polar solvents may be provided.

In the tanks 64 to 66, raw materials are stored which are not recycled by the stripping solution recycling system 1 of the present invention. The stripping solution recycling system 1 of the present invention may discharge some components of the stripping solution 22 when discarding the precipitate and the like, which means that 100% of recycling is not achieved.

A given amount of the separated liquid 50 from the distillation and regeneration device 14 is stored in the preparation tank 60. The component analyzer 62 then determines the composition ratio of the tertiary alkanolamine used as a main agent and the polar solvent with respect to the separated liquid 50 stored in the preparation tank 60. This is because certain amounts of respective components in the separated liquid 50 have been discarded when the precipitate and the residue are discarded, and accordingly the component ratio may be changed.

The component analyzer 62 is not particularly limited as long as it can determine the composition ratio of the main agent and the polar solvent. It may be a measuring instrument utilizing absorbance or may be a measuring instrument utilizing ultrasound.

To the separated liquid 50 in which the composition ratio of the components has been determined, the main agent and the polar solvent are supplied from the tanks 64 to 66 in the raw material tank 20 in order to obtain a predetermined composition ratio. The predetermined composition ratio here means such a ratio that the amount of the tertiary alkanolamine is a given value within the range of from 1% to 9% by mass and the amount of the polar solvent is a given value within the range of from 10% to 70% by mass with respect to the total amount of the stripping solution as described above. The polar solvent here refers to a mixture of two kinds (tanks 65 and 66). The given value here may be appropriately set based on the control error depending on the scale of the entire stripping solution recycling system 1. The main agent and the polar solvent are added and then the water (tank 67) is added at the end to regenerate the mixed solution 32. The regenerated mixed solution 32 is delivered to the supply tank 18.

With reference to FIG. 1 again, the mixed solution 32 obtained from the preparation device 16 is delivered to the supply tank 18. The supply tank 18 is in communication with the stripping solution tank 24 of the stripping device 10 thorough the supply tube 34. The mixed solution 32 in the supply tank 18 is then supplied to the stripping solution tank 24. The mixed solution 32 supplied here also includes, in addition to the tertiary alkanolamine and the polar solvent which are recycled by the stripping solution recycling system 1 of the present invention, the tertiary alkanolamine and the polar solvent which are not recycled by the stripping solution recycling system 1 of the present invention. In this specification, the mixed solution containing the former and the latter is referred to as the “regenerated mixed solution.” The “regenerated mixed solution” and the “mixed solution” are not different in content.

Next, the method for operating the stripping solution recycling system 1 of the present invention will be described. It is supposed that the stripping solution used in the stripping solution recycling system 1 of the present invention obtains the corrosion prevention effect on the Cu film through the exposed resist. As clear from Examples described below, only the mixed solution 32 can also be used as the stripping solution. This may be because the mixed solution 32 serves as the stripping solution at the time when dissolving the resist.

For this reason, only the mixed solution 32 is supplied to the stripping solution tank 24 only at the beginning of the operation of the stripping solution recycling system 1, or when the stripping solution tank 24 is empty. Once the stripping solution recycling system 1 operates, however, the stripping solution 22 is continuously present in the stripping solution tank 24 only by adding the mixed solution 32 with part of the stripping solution 22 left.

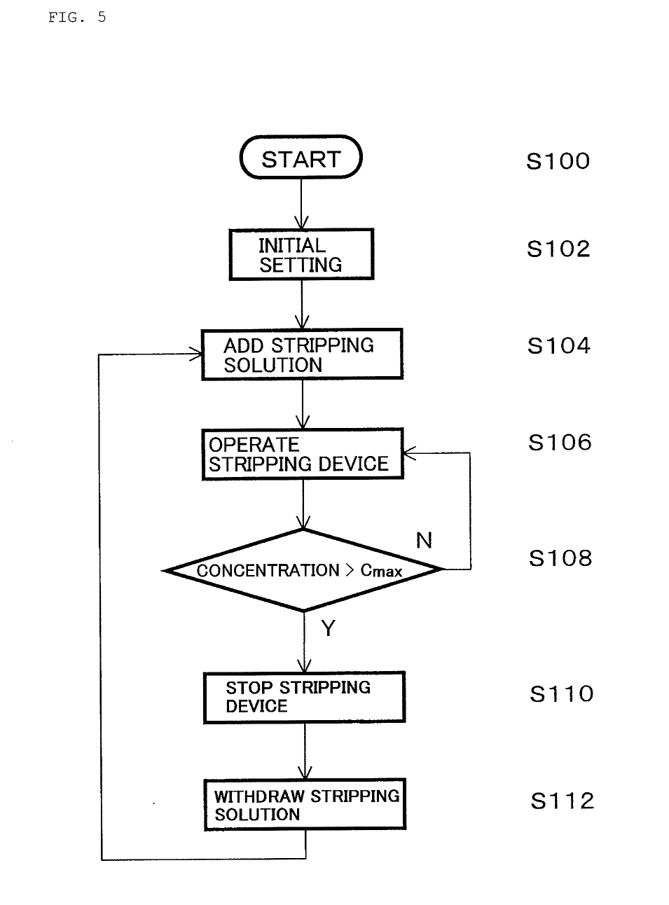

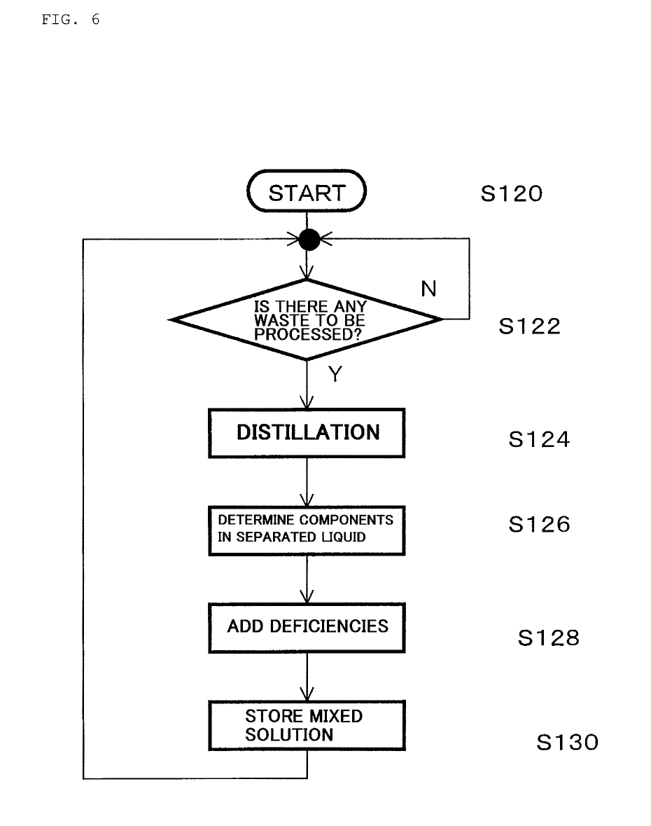

FIGS. 5 and 6 illustrate a process flow of the stripping solution recycling system 1. In the stripping solution recycling system 1 illustrated in FIG. 1, the stripping device 10, the waste tank 12, the distillation and regeneration device 14, and the preparation device 16 can be independently operated. In other words, the stripping device 10 can be operated while the stripping solution 22 is recycled. Then, the process flow of the stripping device 10 is illustrated in FIG. 5, and the process flow in the waste tank 12, the distillation and regeneration device 14, and the preparation device 16 is illustrated in FIG. 6. Reference is appropriately made to FIG. 1.

Referring to FIG. 5, when the stripping solution recycling system 1 operates (Step S100), after initial setting (Step S102), the mixed solution 32 is supplied to the stripping solution tank 24 from the supply tank 18 (Step S104). Subsequently, the stripping device 10 operates (Step S106). Operation of the stripping device 10 refers to removal of the resist on the workpiece 30 with repeated use of the stripping solution 22. During the operation, the resist composition in the stripping solution 22 is monitored with the resist concentration detection means 27 (Step S108). The stripping solution is repeatedly used while the concentration of the resist composition is within a given range. When the concentration of the resist composition reaches a given concentration (Cₘₐₓ) (Y-branch in Step S108), the stripping device 10 stops the operation (Step S110).

The stripping solution 22 in the stripping solution tank 24 is then transferred to the waste tank 12 through the discharge tube 36 (Step S112). The stripping solution 22 in the waste tank 12 is delivered to the distillation and regeneration device 14 to extract the separated liquid 50. The component ratio of the separated liquid 50 is determined and the separated liquid 50 is supplemented with given amounts of respective components by the preparation device 16 to be recycled as the mixed solution 32.

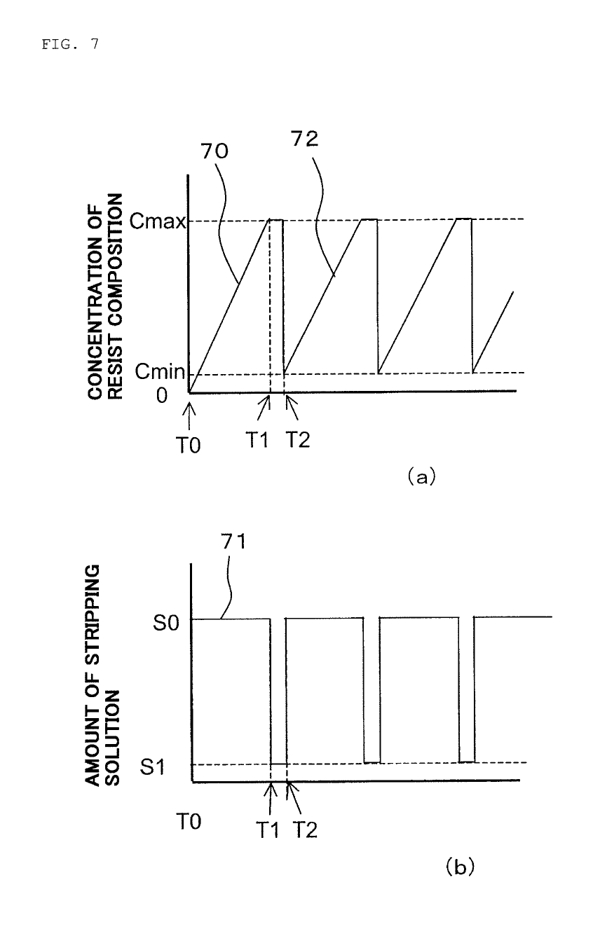

FIG. 7 illustrates graphs conceptually showing the relationship between the concentration of the resist composition (FIG. 7(a)) and the amount of the stripping solution 22 (FIG. 7(b)) in the stripping solution tank 24. In both, the horizontal axis represents the number of processing on the workpiece 30. The period of time while the number of processing is almost constant may be regarded as an operating time. The vertical axis in FIG. 7(a) represents the concentration of the resist composition and the vertical axis in FIG. 7(b) represents the amount of the stripping solution 22 in the stripping solution tank 24. In FIG. 7(a), at the beginning of the operation of the stripping solution recycling system 1, the concentration of the resist composition is zero (T0 point). Referring to FIG. 7(b), the stripping solution tank 24 is supplied with a given amount S0 of the stripping solution 22 at this time.

Once the stripping solution recycling system 1 operates, the resist concentration increases with the amount of the processed resist (70). In the meantime, the amount of the stripping solution 22 remains almost unchanged (71). When the concentration of the resist composition in the stripping solution 22 reaches a given value (Cₘₐₓ) (T1), the operation of the stripping device 10 is stopped. In the case of the stripping solution used in the present invention, the maximum concentration (Cₘₐₓ) of the resist composition is 3000 ppm.

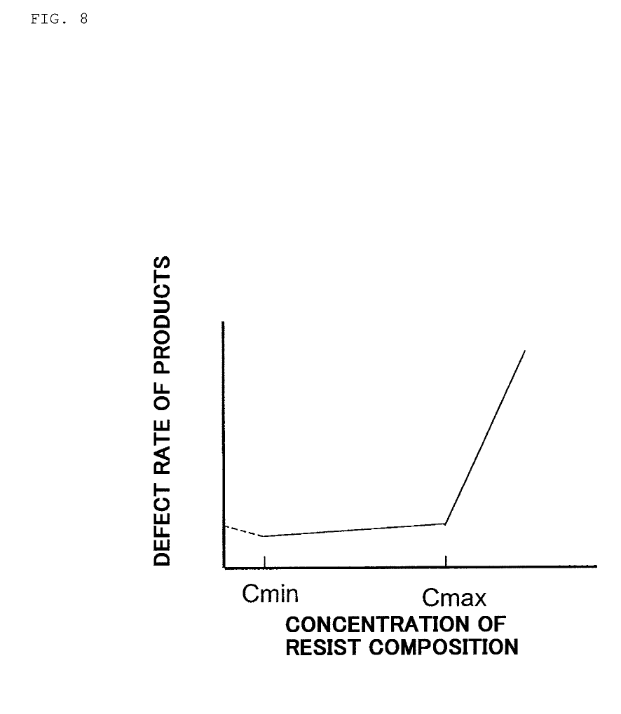

FIG. 8 illustrates a graph conceptually showing relation between the resist composition in the stripping solution and the defect rate of products. The vertical axis represents the defect rate of products and the horizontal axis represents the concentration of the resist composition. The defect rate is low and stable until the concentration of the resist composition reaches Cₘₐₓ. However, the defect rate dramatically increases when the concentration of the resist composition exceeds Cₘₐₓ. This may be because high concentration of the resist composition results in increased number of debris included in the stripping solution 22 and thus the debris cannot be completely removed through the filter 25.

Since the resist composition exerts the corrosion prevention effect on the Cu film, some components may be attached onto the Cu film. Accordingly, the reason of the increased defect rate may also be that high concentration of the resist composition results in increased amounts of the attached components and accordingly lowers the adhesiveness to the film formed on the Cu film.

When the concentration of the resist composition is lower than the minimum concentration Cₘᵢₙ, the defect rate of products increases slightly. However, such situation occurs only at the beginning of operation of the stripping solution recycling system 1, or only when the stripping solution 22 is completely drained out from the stripping solution tank 24. Therefore, such situation does not cause any practical problem.

Reference is made to FIG. 5 again together with FIG. 7. When the stripping device 10 is stopped (Step S110), the stripping solution 22 is transferred to the waste tank 12 (Step S112). Accordingly, the amount of the stripping solution 22 in the stripping solution tank 24 decreases to S1 (see FIG. 7(b)). The amount (S1) of the stripping solution 22 to be left in the stripping solution tank 24 is such an amount that the ratio of the resist composition to the amount (S0) of the stripping solution 22 used during the operation is Cₘᵢₙ (100 ppm). As illustrated below in Example, at least 100 ppm of the resist composition contained allows the positive resist formed on the Cu film to be stably removed and further achieves good adhesiveness to the film formed on the Cu film.

After a given amount of the stripping solution is discharged, the mixed solution 32 is supplied to the stripping solution tank 24 again (Step S104). When the mixed solution 32 is supplied from the supply tank 18 (T2), the amount of the stripping solution 22 reaches a given amount (S0) and the concentration of the resist composition decreases to Cₘᵢₙ (100 ppm) (see T2 in FIG. 7(a)). After that, the stripping device 10 starts the operation again (Step S106), the concentration of the resist composition increases (see reference numeral 72 in FIG. 7(a)), and the same procedure is repeated. In this manner, the stripping solution recycling system 1 of the present invention controls the stripping solution 22 in the stripping solution tank 24 such that the concentration of the resist composition falls within a given range (Cₘᵢₙ to Cₘₐₓ: 100 to 3000 ppm) by taking advantages of the fact that the exposed resist composition on the Cu film exerts a corrosion prevention action of the Cu film.

Next, a process flow in the waste tank 12, the distillation and regeneration device 14, and the preparation device 16 will be described with reference to FIG. 6. The step in the stripping device 10 is for using the stripping solution, whereas the step in the waste tank 12, the distillation and regeneration device 14, and the preparation device 16 is for regenerating the stripping solution. When the process starts (Step S120), whether there is any waste to be processed in the waste tank 12 starts to be determined (Step S122).

When there is a waste to be processed (Y-branch in Step S122), the stripping solution 22 determined as a waste is delivered to the distillation and regeneration device 14 for distillation (Step S124). The distillation in Step S124 includes procedures of removing impurities in the stripping solution 22 through the filter 46 and distilling the stripping solution 22 through the distillation column 48. In the meantime, a step of eliminating a precipitate from the waste tank 12 is carried out as appropriate.

When the separated liquid 50 is obtained from the distillation and regeneration device 14, components in the separated liquid 50 are determined (Step S126). The determination of the components in the separated liquid 50 means determination of the composition ratio of the tertiary alkanolamine and the polar solvent in the separated liquid 50. Subsequently, deficiencies of the respective components are added so as to obtain a given ratio of the components (Step S128). Here, the water 52 is also added at the end to prepare the mixed solution 32. The final mixed solution 32 is stored in the supply tank 18 (Step S130).

As described above, the stripping solution 22 is used in the stripping device 10 and regenerated in the waste tank 12, the distillation and regeneration device 14, and the preparation device 16. Each of these steps can be carried out independently. Accordingly, each step can be continuously operated by disposing an appropriate tank for storage according to the amount of the stripping solution 22 used.

The stripping solution recycling system 1 of the present invention does not use trace additives such as a corrosion inhibitor conventionally required for removing a resist on a Cu film. Therefore, the tertiary alkanolamine and the polar solvent can be easily recovered as the separated liquid 50. This is because their boiling points are higher than water and the melting point itself of the resist composition serving as a corrosion inhibitor is much higher than that of the tertiary alkanolamine, the polar, or the like. The fact of not using trace additives means that there is no additives to be concentrated every time the stripping solution is recycled and thus the defect rate of products does not increase no matter how many times the stripping solution is recycled.

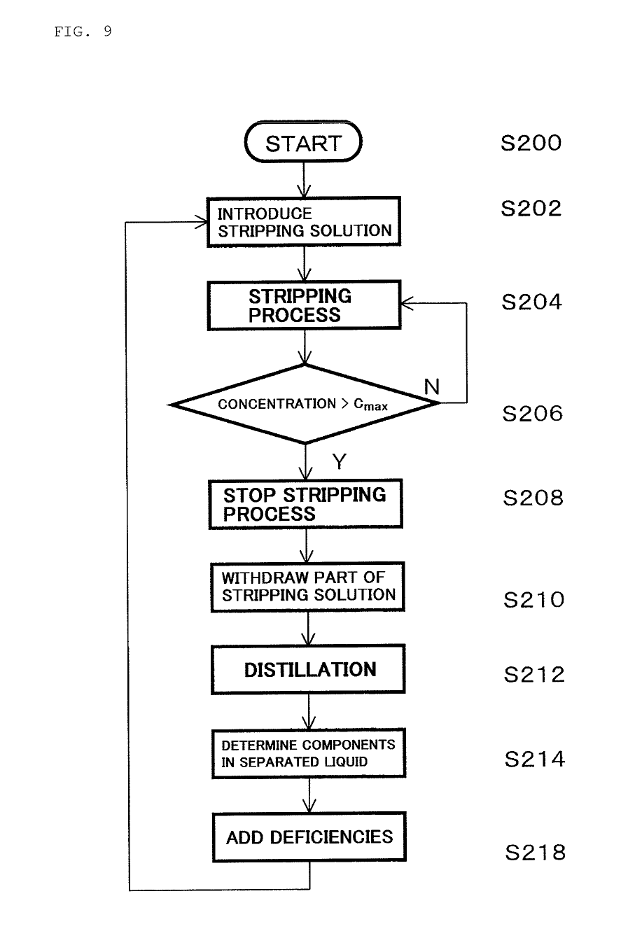

It can also be said that the method for operating the stripping solution recycling system 1 of the present invention as described above also refers to a method for recycling the stripping solution itself used in the present invention from a different standpoint. In order to clarify this, a flow of the method for recycling the stripping solution 22 is illustrated in FIG. 9. It may be considered that this flow is obtained by connecting the flows illustrated in the method for operating the stripping solution recycling system 1.

In the description of FIG. 9, the stripping solution refers to a photoresist stripping solution including 1% to 9% by mass of the tertiary alkanolamine, 10% to 70% by mass of the polar solvent, 10% to 40% by mass of the water, and 3000 ppm or less of the resist composition. That is, the case where the concentration of the resist composition is zero is also referred to as the “stripping solution.”

Once the exposed positive resist is dissolved out into the mixed solution, the mixed solution serves as the stripping solution for the positive resist film having a corrosion prevention function for the Cu film, as already described. Therefore, the mixed solution free from the resist composition (the mixed solution including the tertiary alkanolamine, the polar solvent, and the water) can also be referred to as the stripping solution, assuming that it is used for the exposed positive resist film.

When a stripping process starts (Step S200), the stripping solution is introduced into the process vessel where the stripping process is conducted (Step S202), and the stripping process is conducted (Step S204). The stripping process here refers to the process of stripping the positive resist film which is formed on the Cu film and exposed to light. The stripping solution is monitored for its concentration of the resist composition and repeatedly used unless the concentration of the resist composition exceeds a given value (Cₘₐₓ) (N-branch in Step S206).

When the resist concentration exceeds a given value (Y-branch in Step S206), the stripping process is stopped (Step S208) and part of the stripping solution is withdrawn (Step S210). The withdrawn stripping solution is distilled to extract the separated liquid including the tertiary alkanolamine and the polar solvent (Step S212). The composition ratio of the tertiary alkanolamine and the polar solvent in the separated liquid is determined (Step S214) on the other hand, and components deficient as the stripping solution are added (Step S218).

The stripping solution (not including the resist composition here) regenerated in this manner is introduced into the process vessel (Step S202) and mixed with the remaining stripping solution again, and the stripping process is conducted (Step S204). In this case, the stripping solution once regenerated is additionally poured into the stripping solution which is not regenerated (which is left) and thus continues to exist in the process vessel as the stripping solution that always contains the resist composition from the exposed resist film having the corrosion prevention effect on the Cu film.

In this manner, the stripping solution used in the present invention obtains the corrosion prevention effect on the Cu film through the exposed resist film itself, and therefore the tertiary alkanolamine used as a main agent, the polar solvent, and the water can be easily separated according to the above steps. That is, trace components such as trace additives are not carelessly concentrated. As a result, the stripping solution can be regenerated over and over as the stripping solution for the resist on the Cu film.

### Second Embodiment

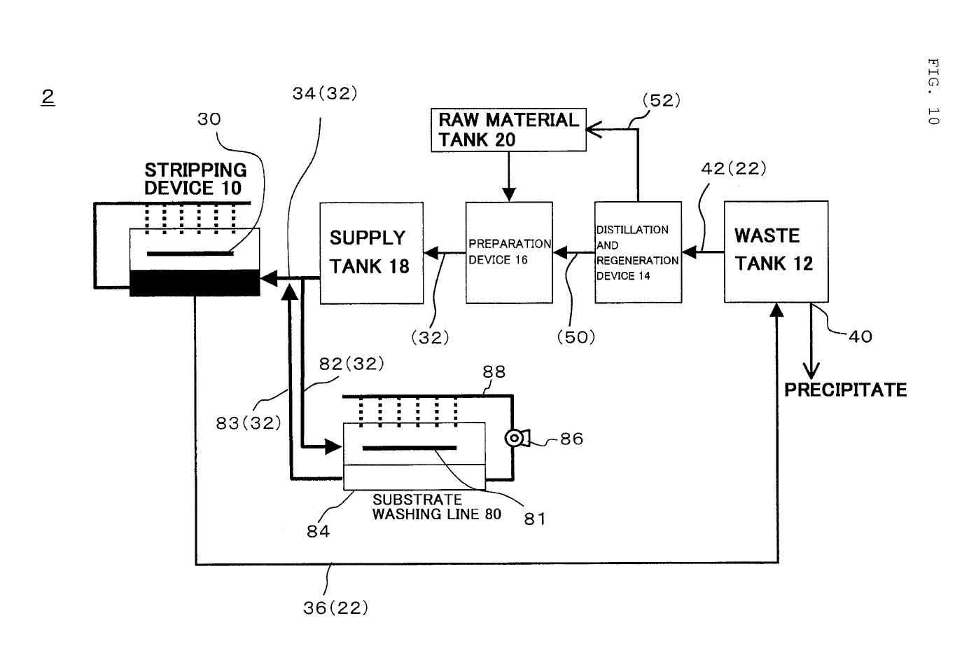

FIG. 10 illustrates the configuration of a stripping solution recycling system 2 of the present embodiment. The stripping solution recycling system 1 of the first embodiment can recycle the stripping solution having a corrosion prevention function for the Cu film over and over as described above. This regenerated mixed solution 32 does not include impurities other than the tertiary alkanolamine, the polar solvent, and the water. Accordingly, it can be used for washing a substrate of a workpiece.

FIG. 10 illustrates the stripping solution recycling system 2 where a substrate washing line 80 is provided in the stripping solution recycling system 1 of FIG. 1. The substrate washing line 80 is a line for washing a glass substrate 81 stored during work-in-process and a glass substrate 81 before a Cu film is formed thereon (hereinafter, collectively referred to as a “substrate and the like”) with the mixed solution 32 before transferring to the next step. The substrate 81 and the like during work-in-process are stored in a controlled environment. However, direct transfer of the stored substrate 81 and the like to the next step has caused a problem of poor adhesiveness to a film to be deposited thereon.

Although the reason is not clear, this may be because the surface of the substrate 81 and the like are slightly oxidized or so during storage. However, washing of the substrate 81 and the like with mixed solution 32 significantly improves the adhesiveness to the film to be next deposited thereon. It seems that this is because, since the mixed solution 32 is alkaline due to the tertiary alkanolamine included therein, the oxidized layer on the surface of the substrate 81 and the like is gently washed off to activate the surface of the substrate 81 and the like.

The substrate washing line 80 receives supply of the mixed solution 32 through a branch tube 82 from the supply tube 34 which is a supply line of the mixed solution 32. Like the stripping device 10, the substrate washing line 80 has a washing tank 84 for storing the mixed solution 32, a pump 86, and a shower 88. Substrate transfer means not shown is provided, allowing the substrate 81 and the like to pass under the shower 88 of the substrate washing line 80 and then to be transferred to the next step.

The mixed solution 32 in the washing tank 84 is delivered to the shower 88 with the pump 86, and showered down on the substrate 81 and the like passing under the shower 88 to wash the surface of the substrate 81 and the like. In the substrate washing line 80, there is no component dissolved out of the substrate 81 and the like. Therefore, after the mixed solution 32 is used to some extent, it can be delivered to the stripping device 10 through a return tube 83 and used as the mixed solution 32 for removing the resist. The mixed solution 32 in the return tube 83 may be returned to the supply tube 34, or may be directly delivered to the stripping solution tank 24 in the stripping device 10.

### EXAMPLES

Although Examples of the stripping solution of the present invention are illustrated below together with Comparative Examples, the stripping solution of the present invention is not limited to the following Examples. First, preparation and evaluation methods of samples will be described.

<Method for Producing Evaluation Substrate>

In order to demonstrate the effect of the photoresist stripping solution which is the stripping solution of the present invention, an evaluation substrate was produced according to the following procedure. This is the process usually using a 6-inch wafer and is called a spin processor. First, a film of indium tin oxide (ITO: transparent electrode) was formed on a 6-inch wafer shaped glass substrate (thickness: 1 mm) by sputtering. The thickness of the film was 0.2 μm (2,000 angstroms).

Next, a Cu film for gate lines was formed in a thickness of about 0.3 μm on the ITO film by deposition. Next, a is positive resist was coated thereon in a thickness of 1 μm by a spinner. After the resist film was formed, prebaking was performed for 2 minutes in an environment of 100° C.

Next, the resist film was exposed to light using a photomask. A straight pattern having a width of 5 μm was used as the photomask. Then, development was performed using tetramethylammonium hydroxide (TMAH). This removed the exposed part of the photoresist.

Etching was performed for 1 minute using an oxidizing etchant heated to 40° C. This process removed the Cu film except for the part where the photoresist remained. The processed substrate was washed with running pure water for 1 minute. The washed substrate was dried in a spin dryer at 8,000 rpm for 1 minute and stored. At this time, nitrogen gas after passing through a filter was sprayed from a rotation center at a flow rate of 0.5 m³/s.

<Corrosion Prevention Property of Cu Film>

The corrosion prevention property of the Cu film was evaluated according to the following procedure. First, a substrate was cut into strips of 10 mm×60 mm such that gate lines (made of the Cu film) were in the longitudinal direction. Twenty ml of the stripping solution prepared with the composition shown in Table 1 was dispensed into a vial bottle (30 ml). Then, the stripping solution in the vial bottle was heated to 40° C. in a water bath. Subsequently, the prepared evaluation substrate was immersed in the stripping solution at 40° C. for 30 minutes. Since this evaluation is an experiment for investigating the capability of the stripping solution to corrode Cu, the immersion time was long such as 30 minutes.

The evaluation substrate was taken out of the stripping solution after the immersion and washed with running pure water for 1 minute. The evaluation substrate was dried in dry air after washed. The dry air had passed through a filter, but the temperature was a room temperature. The processed substrate was observed for its surface and cross section under a scanning electron microscope (SEM), and the stripping solution left in the vial bottle was analyzed for the concentration of Cu by atomic absorption spectrophotometry.

The processed substrate was evaluated according to the following criteria for the observation under the SEM. In the plane observation of the processed substrate under the SEM at a magnification of 800 times and the cross-sectional observation at a magnification of 3,000 times, that with no observed corrosion was evaluated as circle, “without corrosion.” That with a decreased line width and thickness but with wiring being left was evaluated as triangle, “with corrosion.” That with no wiring was evaluated as cross, “with severe corrosion.” Respective marks were shown in Table 1. The corrosion prevention property of the Cu film was expressed as “PC” in Table 1.

<Resist Stripping Property>

The photoresist stripping property was evaluated in the same procedure as the corrosion prevention property of the Cu film. Specific procedure was as follows. First, a substrate was cut into strips of 10 mm×60 mm such that gate lines (made of the Cu film) were in the longitudinal direction. Twenty ml of the stripping solution prepared with the composition shown in Table 1 was dispensed into a vial bottle (30 ml). Then, the stripping solution in the vial bottle was heated to 40° C. in a water bath. Subsequently, the prepared evaluation substrate was immersed in the stripping solution at 40° C. for 30 seconds.

The evaluation substrate was taken out of the stripping solution after the immersion and washed with running pure water for 1 minute. The evaluation substrate was dried in dry air after washed. The dry air had passed through a filter, but the temperature was a room temperature. The processed substrate was observed for its surface under a SEM.

The stripping property was evaluated according to the following criteria in the observation under the SEM. If there was no residue of a resist over the full length (60 mm) of the evaluation substrate by the plane observation under the SEM at a magnification of 800 times, it was evaluated as circle, “without residue.” If there was a residue, or if there was no meaning of the evaluation due to severe corrosion of the Cu film, a minus sign (“−”) was provided as “not evaluated.” The resist stripping property was expressed as “RR” in Table 1.

<Resist Solubility>

The stripping solution was evaluated for its resist solubility as follows. In this Example, a photoresist is denatured and cannot be easily stripped since the photoresist is exposed to an oxidizing etchant. First, a substrate was cut into strips of 20 mm×60 mm such that gate lines (made of the Cu film) were in the longitudinal direction. Fifty ml of the stripping solution prepared with the composition shown in Table 1 was dispensed into a vial bottle (50 ml). Then, the stripping solution in the vial bottle was heated to 40° C. in a water bath. Subsequently, the prepared evaluation substrate was placed in the stripping solution at 40° C. and the time until the resist floated up was measured with a stopwatch.

The resist solubility was evaluated according to the following criteria. If the resist dissolved within 30 seconds after the evaluation substrate was immersed in the stripping solution, it was evaluated as circle, “with sufficient solubility.” If it took 30 seconds or more, it was evaluated as cross, “without sufficient photoresist solubility.” The resist solubility was expressed as “RS” in Table 1.

<Film Peeling>

Even if the stripping solution dissolved a sufficient amount of the photoresist which was denatured due to exposure to an oxidizing etchant and did not cause the corrosion of the Cu film, it cannot be said that the stripping solution is practical when a corrosion inhibitor remained on the Cu film surface and the adhesiveness to a film formed thereon was poor. Here, film peeling was evaluated as follows given that the corrosion inhibitor on the Cu film surface was too little to cause any practical problem, or sufficient to form the film on the Cu film without any practical problem.

First, a substrate was cut into strips of 10 mm×60 mm such that gate lines (made of the Cu film) were in the longitudinal direction. Twenty ml of the stripping solution prepared with the composition shown in Table 1 was dispensed into a vial bottle (30 ml). Then, the stripping solution in the vial bottle was heated to 40° C. in a water bath. Subsequently, the prepared evaluation substrate was immersed in the stripping solution at 40° C. for 30 seconds. The evaluation substrate was then taken out of the stripping solution and washed with running pure water for 1 minute. After washed, the evaluation substrate was dried in dry air at a flow rate of 0.8 m³/s at room temperature for 2 minutes.

An insulating film (SiO₂) of 0.1 μm thickness was formed by sputtering on the Cu-film formed surface of the substrate. Subsequently, a gold film of approximately 0.01 μm was further formed on the insulating film by sputtering and observed under a SEM at a magnification of 1,000 times. The film peeling was evaluated according to the following criteria. If the films were integrally formed on the Cu film, it was evaluated as circle, “without film peeling.” If there was peeling or pores of SiO₂ observed in some of edge parts or flat parts of the Cu film, it was evaluated as cross, “with film peeling.” The insulating film on the Cu film needs to be strictly evaluated since incomplete insulation causes a short circuit and directly leads to a defect. The film peeling was expressed as “AS” in Table 1.

In addition to the above evaluation, the composition and pH of the stripping solution are shown in Table 1. As amines, monoethanolamine (MEA) being a primary alkanolamine and N-methyldiethanolamine (MDEA) being a tertiary alkanolamine were used for comparison. In Comparative Examples, benzotriazole (BTA), pyrocatechol, vitamin C, and sorbitol were used as corrosion inhibitors. The composition and the evaluation results in Examples and respective Comparative Examples will be described below.

### Example 1

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, and 31% by mass of water. The pH was 10.6.

Although the corrosion prevention property of the Cu film was evaluated as triangle, the resist stripping property, the resist solubility, and the film peeling of an insulating film stacked on the copper layer were evaluated as circle. The amount of copper dissolved out in the stripping solution was 0.79 ppm, which did not cause any practical problem. Although not included in Comparative Examples, it was confirmed that, with respect to a sample without the resist film but with only the Cu film, the stripping solution in Example 1 was evaluated as cross for the corrosion prevention property of the Cu film. The amount of copper dissolved out in the stripping solution was expressed as “CD” in Table 1.

### Example 2

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, and 30.99% by mass of water. This was called a mixed solution.

A resist composition was prepared as follows. First, a positive resist was coated in 1 μm thickness on a glass substrate by a spinner. The positive resist used here was the same as that used in producing the evaluation substrate. Next, this resist film was exposed to light. The exposing conditions were also the same as those used in producing the evaluation substrate. The exposed resist film formed on the glass substrate was dissolved by the mixed solution, and the weight of the resist film formed on the glass substrate was obtained from the difference in weight of the substrate before and after the resist film was dissolved. That is, when the resist film of the “glass substrate with the exposed resist film” produced in the same manner is dissolved in the mixed solution, a stripping solution containing a given resist composition can be obtained. Hereinafter, this is called an “exposed resist film piece.”

The exposed resist film piece becomes a resist composition when dissolved into the mixed solution. As much as 0.01% by mass of the exposed resist film piece was prepared and mixed into the mixed solution warmed to 40° C. The exposed resist film piece was easily dissolved. A mixture of MDEA, BDG, PG, water, and the exposed resist film piece was provided as the stripping solution of this Example. The pH was 10.4.

Although the corrosion prevention property of the Cu film was evaluated as triangle, the resist stripping property, the resist solubility, and the film peeling of the insulating film formed on the Cu film were all evaluated as circle. The amount of copper dissolved out in the stripping solution was 0.77 ppm, which did not cause any practical problem.

### Example 3

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, 30.95% by mass of water, and 0.05% by mass of the exposed resist film piece. The pH was 10.2.

The corrosion prevention property of the Cu film, the resist stripping property, the resist solubility, and the film peeling of the insulating film formed on the Cu film were all evaluated as circle. The amount of copper dissolved out in the stripping solution was 0.35 ppm, which did not cause any practical problem.

### Example 4

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, 30.9% by mass of water, and 0.1% by mass of the exposed resist film piece. The pH was 10.0.

The corrosion prevention property of the Cu film, the resist stripping property, the resist solubility, and the film peeling of the insulating film formed on the Cu film were all evaluated as circle. The amount of copper dissolved out in the stripping solution was 0.30 ppm, which did not cause any practical problem.

### Example 5

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, 30.8% by mass of water, and 0.2% by mass of the exposed resist film piece. The pH was 9.9.

The corrosion prevention property of the Cu film, the resist stripping property, the resist solubility, and the film peeling of the insulating film formed on the Cu film were all evaluated as circle. The amount of copper dissolved out in the stripping solution was 0.26 ppm, which did not cause any practical problem.

### Example 6

A stripping solution with the following composition was prepared. The stripping solution included 5% by mass of MDEA (N-methyldiethanolamine) as an amine, 40% by mass of BDG (diethylene glycol monobutyl ether) and 24% by mass of PG (propylene glycol) as polar solvents, 30.7% by mass of water, and 0.3% by mass of the exposed resist film piece. The pH was 9.8.

The corrosion prevention property of the Cu film, the resist stripping property, the resist solubility, and the film peeling of the insulating film formed on the Cu film were all evaluated as circle. The amount of copper dissolved out in the stripping solution was 0.23 ppm, which did not cause any practical problem.

### Comparative Example 1

A stripping solution with the following composition was prepared. The stripping solution included 5% by mass of MDEA as an amine, 40% by mass of BDG and 24% by mass of PG as polar solvents, 0.1% by mass of BTA as a corrosion inhibitor, and 30.9% by mass of water. The pH was 10.0.

The corrosion prevention property of the Cu film and the resist stripping property were evaluated as circle. However, the resist solubility and the film peeling of the insulating film formed on the Cu film were both evaluated as cross. The amount of copper dissolved out in the stripping solution was less than 0.05 ppm. This was because the stripping solution did not corrode the Cu film surface due to its poor resist solubility. Although the corrosion prevention property of the Cu film was improved, the insulating film formed on the Cu film was peeled.

### Comparative Example 2

A stripping solution with the following composition was prepared. The stripping solution included 5% by mass of MEA (monoethanolamine) as an amine, 42% by mass of BDG and 18% by mass of PG as polar solvents, 0.1% by mass of BTA as a corrosion inhibitor, and 34.9% by mass of water. The pH was 10.7.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 3

A stripping solution with the following composition was prepared. The stripping solution included 5% by mass of MEA (monoethanolamine) as an amine, 42% by mass of BDG and 18% by mass of PG as polar solvents, 0.49% by mass of BTA as a corrosion inhibitor, and 34.51% by mass of water. The pH was 10.5.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 4

A stripping solution with the following composition was prepared. The stripping solution included 5% by mass of MEA (monoethanolamine) as an amine, 42% by mass of BDG and 18% by mass of PG as polar solvents, 0.98% by mass of BTA as a corrosion inhibitor, and 34.02% by mass of water. The pH was 10.5.

The corrosion prevention property of the Cu film was evaluated as cross. The copper layer was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 5

A stripping solution with the following composition was prepared. The stripping solution included 5% by mass of MEA (monoethanolamine) as an amine, 42% by mass of BDG and 18% by mass of PG as polar solvents, 5% by mass of pyrocatechol as a corrosion inhibitor, and 30% by mass of water. The pH was 10.3.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 6

A stripping solution with the following composition was prepared. The stripping solution included 20% by mass of MEA (monoethanolamine) as an amine, 60% by mass of BDG as a polar solvent, 5% by mass of pyrocatechol as a corrosion inhibitor, and 15% by mass of water. The pH was 11.2.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 7

A stripping solution with the following composition was prepared. The stripping solution included 5% by mass of MEA (monoethanolamine) as an amine, 42% by mass of BDG and 18% by mass of PG as polar solvents, 1% by mass of BTA and 1% by mass of vitamin C as corrosion inhibitors, and 33% by mass of water. The pH was 10.3.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 8

A stripping solution with the following composition was prepared. The stripping solution included 5% by mass of MEA (monoethanolamine) as an amine, 42% by mass of BDG and 18% by mass of PG as polar solvents, 1% by mass of BTA and 1% by mass of sorbitol as corrosion inhibitors, and 33% by mass of water. The pH was 10.5.

The corrosion prevention property of the Cu film was evaluated as cross. The Cu film was lost due to severe corrosion of the Cu film surface and thus the evaluation of the stripping property was impossible. The resist solubility was evaluated as circle. Since the Cu film itself was lost, it was, of course, not worth evaluating the stripping property of the insulating film.

### Comparative Example 9

A stripping solution with the following composition was prepared. The stripping solution included 5% by mass of MDEA as an amine, 40% by mass of BDG and 24% by mass of PG as polar solvents, 1% by mass of BTA and 1% by mass of sorbitol as corrosion inhibitors, and 29% by mass of water. The pH was 9.1.

The corrosion prevention property of the Cu film and the resist stripping property were evaluated as circle. However, the resist solubility and the film peeling of the insulating film formed on the Cu film were both evaluated as cross. The amount of copper dissolved out in the stripping solution was less than 0.05 ppm. This was because the stripping solution did not corrode the Cu film surface due to its poor resist solubility. Although the corrosion prevention property of the Cu film was improved, the insulating film stacked on the Cu film was peeled.

TABLE 1

| | COMPOSITION OF STRIPPING SOLUTION [wt %] | | | | | | | |
|---|---|---|---|---|---|---|---|---|
| | | | POLAR | | CORROSION INHIBITOR | | | |
| EXPERIMENT | AMINE | | SOLVENT | | | PYRO- | | |
| NUMBER | MEA | MDEA | BDG | PG | BTA | CATECHOL | VITAMIN C | SORBITOL |
| EXAMPLE 1 | — | 5 | 40 | 24 | 0 | — | — | — |
| EXAMPLE 2 | — | 5 | 40 | 24 | 0 | — | — | — |
| EXAMPLE 3 | — | 5 | 40 | 24 | 0 | — | — | — |
| EXAMPLE 4 | — | 5 | 40 | 24 | 0 | — | — | — |
| EXAMPLE 5 | — | 5 | 40 | 24 | 0 | — | — | — |
| EXAMPLE 6 | — | 5 | 40 | 24 | 0 | — | — | — |
| COMPARATIVE | — | 5 | 40 | 24 | 0.1 | — | — | — |
| EXAMPLE 1 | | | | | | | | |
| COMPARATIVE | 5 | — | 42 | 18 | 0.1 | — | — | — |
| EXAMPLE 2 | | | | | | | | |
| COMPARATIVE | 5 | — | 42 | 18 | 0.49 | — | — | — |
| EXAMPLE 3 | | | | | | | | |
| COMPARATIVE | 5 | — | 42 | 18 | 0.98 | — | — | — |
| EXAMPLE 4 | | | | | | | | |
| COMPARATIVE | 5 | — | 42 | 18 | | 5 | — | — |
| EXAMPLE 5 | | | | | | | | |
| COMPARATIVE | 20 | — | 60 | | | 5 | — | — |
| EXAMPLE 6 | | | | | | | | |
| COMPARATIVE | 5 | — | 42 | 18 | 1 | — | 1 | — |
| EXAMPLE 7 | | | | | | | | |
| COMPARATIVE | 5 | — | 42 | 18 | 1 | — | — | 1 |
| EXAMPLE 8 | | | | | | | | |
| COMPARATIVE | — | 5 | 40 | 24 | 1 | — | — | 1 |
| EXAMPLE 9 | | | | | | | | |

| | COMPOSITION OF | | | | | | | | |
|---|---|---|---|---|---|---|---|---|---|
| | STRIPPING SOLUTION [wt %] | | | | | | | | |
| EXPERIMENT | | WATER | | | | | | | CD |
| NUMBER | RESIST | CONTENT | TOTAL | pH | PC | RR | RS | AS | [ppm] |
| EXAMPLE 1 | — | 31 | 100 | 10.6 | Δ | ◯ | ◯ | ◯ | 0.79 |
| EXAMPLE 2 | 0.01 | 30.99 | 100 | 10.4 | Δ | ◯ | ◯ | ◯ | 0.77 |
| EXAMPLE 3 | 0.05 | 30.95 | 100 | 10.2 | ◯ | ◯ | ◯ | ◯ | 0.35 |
| EXAMPLE 4 | 0.1 | 30.9 | 100 | 10.0 | ◯ | ◯ | ◯ | ◯ | 0.3 |
| EXAMPLE 5 | 0.2 | 30.8 | 100 | 9.9 | ◯ | ◯ | ◯ | ◯ | 0.26 |
| EXAMPLE 6 | 0.3 | 30.7 | 100 | 9.8 | ◯ | ◯ | ◯ | ◯ | 0.23 |
| COMPARATIVE | — | 30.9 | 100 | 10.0 | ◯ | ◯ | X | X | LESS THAN |
| EXAMPLE 1 | | | | | | | | | 0.05 |
| COMPARATIVE | — | 34.9 | 100 | 10.7 | X | — | ◯ | — | — |
| EXAMPLE 2 | | | | | | | | | |
| COMPARATIVE | — | 34.51 | 100 | 10.5 | X | — | ◯ | — | — |
| EXAMPLE 3 | | | | | | | | | |
| COMPARATIVE | — | 34.02 | 100 | 10.5 | X | — | ◯ | — | — |
| EXAMPLE 4 | | | | | | | | | |
| COMPARATIVE | — | 30 | 100 | 10.3 | X | — | ◯ | — | — |
| EXAMPLE 5 | | | | | | | | | |
| COMPARATIVE | — | 15 | 100 | 11.2 | X | — | ◯ | — | — |
| EXAMPLE 6 | | | | | | | | | |
| COMPARATIVE | — | 33 | 100 | 10.3 | X | — | ◯ | — | — |
| EXAMPLE 7 | | | | | | | | | |
| COMPARATIVE | — | 33 | 100 | 10.5 | X | — | ◯ | — | — |
| EXAMPLE 8 | | | | | | | | | |
| COMPARATIVE | — | 29 | 100 | 9.1 | ◯ | ◯ | X | X | 0.05 [symbol] |
| EXAMPLE 9 | | | | | | | | | |

PC: CORROSION PREVENTION PROPERTY OF Cu FILM
RR: RESIST STRIPPING PROPERTY
RS: RESIST SOLUBILITY
AS: FILM PEELING
CD: AMOUNT OF Cu DISSOLVED OUT IN STRIPPING SOLUTION

Comparative Example 1 and Examples have the same solution composition, but include a different corrosion inhibitor, the resist composition or BTA. The mixed solution including MDEA (N-methyldiethanolamine) as a main component originally has a corrosive action on the Cu film. However, BTA or the resist composition can suppress corrosion within a practically acceptable range. The resist solubility was evaluated as circle in Examples, whereas it was evaluated as cross in Comparative Example 1 (BTA).

Considering that Example 1 does not include a corrosion inhibitor, it is supposed that the mixed solutions of Examples and Comparative Example 1 themselves can dissolve the resist. It was then supposed that the resist did nit dissolve in Comparative Example 1 because of the effect of BTA, a corrosion inhibitor. That is, it is supposed that components added as corrosion inhibitors also suppress the solubility of the resist film itself to some extent.

However, it can be said that the resist composition dissolved out of the exposed resist composition into the mixed solution serves as a corrosion inhibitor and does not prevent the mixed solution of the stripping solution from dissolving the exposed resist.

Comparative Examples 2 to 8 are samples where a main component of the mixed solution is changed into MEA (monomethyl ether). MEA, a primary amine, was highly corrosive and it was not able to suppress its corrosive power even though a considerable amount of BTA, pyrocatechol, vitamin C, or sorbitol was added as a corrosive agent.

Comparative Example 9 is a sample where a main component of the mixed solution is changed back to MDEA and 2% by mass of BTA and sorbitol are included in total. However, although the corrosion prevention effect on the Cu film was observed, the resist solubility was evaluated as cross as in Comparative Example 1.

The above results indicated that the stripping solution used in the present invention was very weak in corrosion effect on the Cu film and moreover capable of dissolving the resist, and also provided good adhesiveness to the layer formed on the Cu film. In addition, as already described, this resist composition includes the photosensitive agent (or a modified photosensitive agent) and the resin, and thus this can be easily separated from the mixed solution in the stripping solution. Therefore, even if the stripping solution is repeatedly used to be a waste, only the mixed solution can be separated and recovered.

More specifically, the amine and the polar solvent can be collectively separated and recovered. The ratio of these components can be easily determined by preparing a calibration curve or the like in advance. Therefore, the stripping solution is supplemented with deficiencies of components based on a predetermined component ratio and further water is added thereto, thereby regenerating the stripping solution. In addition, this regenerated stripping solution did not contain trace additives and thus there is no risk of concentration of trace components even if the stripping solution is regenerated again and again. That is, the stripping solution can be stably recycled.

### INDUSTRIAL APPLICABILITY

The stripping solution of the present inventions can be suitably utilized in products produced by wet etching using Cu films as leads, particularly in general FPDs such as liquid crystal displays, plasma displays, and organic EL displays, which have a large area and require fine processing. The stripping solution recycling system using the stripping solution of the present invention can also be suitably utilized in production of products produced by wet etching using Cu films as leads, particularly general FPDs such as liquid crystal displays, plasma displays, and organic EL displays, which have a large area and require fine processing.

### REFERENCE SIGNS LIST

1, 2 Stripping solution recycling system
10 Stripping device
12 Waste tank
14 Distillation and regeneration device
16 Preparation device
18 Supply tank
20 Raw material tank
21 Chamber
22 Stripping solution
24 Stripping solution tank
25 Filter
26 Pump
27 Resist concentration detection means
28 Shower
30 Workpiece
32 Mixed solution
33 Mixed-solution supply port
34 Supply tube
35 Discharge port
36 Discharge tube
40 Discharge port
42 Transfer pipe
46 Filter
48 Distillation column
50 Separated liquid
52 Water
54 Residue
60 Preparation tank
62 Component analyzer
64 Tank for tertiary alkanolamine
65 Tank for (first) polar solvent
66 Tank for (second) polar solvent
67 Tank for water

1. A photoresist stripping solution comprising: 1% to 9% by mass of a tertiary alkanolamine, 10% to 70% by mass of a polar solvent, 10% to 40% by mass of water, and 3000 ppm or less of a resist composition.

2. The photoresist stripping solution according to claim 1, wherein the tertiary alkanolamine is N-methyldiethanolamine (MDEA).

3. The photoresist stripping solution according to claim 2, wherein the resist composition is originated from an exposed positive photoresist.

4. The photoresist stripping solution according to claim 2, wherein the polar solvent is a mixed solvent of diethylene glycol monobutyl ether and propylene glycol.

5. The photoresist stripping solution according to claim 4, wherein the resist composition is originated from an exposed positive photoresist.

6. The photoresist stripping solution according to claim 1, wherein the polar solvent is a mixed solvent of diethylene glycol monobutyl ether and propylene glycol.

7. The photoresist stripping solution according to claim 6, wherein the resist composition is originated from an exposed positive photoresist.

8. The photoresist stripping solution according to claim 1, wherein the resist composition is originated from an exposed positive photoresist.

9. The photoresist stripping solution according to claim 1, wherein the stripping solution is one for stripping a positive photoresist coated on a Cu film.

10. A method for recycling a photoresist stripping solution, the photoresist stripping solution comprising 1% to 9% by mass of a tertiary alkanolamine, 10% to 70% by mass of a polar solvent, 10% to 40% by mass of water, and 3000 ppm or less of a resist composition, the method comprising the steps of:
introducing the stripping solution into a process vessel where a stripping process is conducted;
conducting the stripping process;
monitoring a resist concentration in a stripping process solution;
stopping the stripping process when a concentration of the resist composition in the stripping solution exceeds a given value, and withdrawing part of the stripping solution;
extracting a separated liquid containing the tertiary alkanolamine and the polar solvent by distilling the withdrawn stripping solution;
regenerating the stripping solution by adding components deficient as the stripping solution to the separated liquid; and
introducing the regenerated stripping solution into the process vessel again.

11. A stripping solution recycling system that regenerates and uses a stripping solution for stripping an exposed positive resist film which is formed on a Cu film, the stripping solution recycling system comprising:
a stripping solution tank for storing therein a stripping solution comprising a resist composition and a mixed solution comprising a main agent, a polar solvent, and water;
removing means for removing an exposed positive resist film on a workpiece repeatedly using the stripping solution in the stripping solution tank;
a supply tube for supplying the mixed solution to the stripping solution tank;
a discharge tube for discharging part of the stripping solution in the stripping solution tank;
a resist stripping device for discharging part of the stripping solution from the discharge tube when a resist concentration of the stripping solution reaches a given value and receiving supply of a fresh stripping solution from the supply tube;
a waste tank for storing therein the discharged stripping solution, the waste tank being connected to the discharge tube;
a distillation and regeneration device for distilling the discharged stripping solution in the waste tank to obtain a separated liquid containing the main agent and the polar solvent;
a component analyzer for investigating a composition ratio of the main agent and the polar solvent in the separated liquid;
a preparation device for preparing a regenerated mixed solution by adding deficiencies of the main agent, the polar solvent, and water to show a predetermined proportion of the main agent, the polar solvent, and the water in the separated liquid; and
a supply tank for storing therein the regenerated mixed solution.

12. The stripping solution recycling system according to claim 11, wherein the stripping solution includes 1% to 9% by mass of a tertiary alkanolamine, 10% to 70% by mass of a polar solvent, 10% to 40% by mass of water, and 100 ppm to 3000 ppm of the resist composition.

13. The stripping solution recycling system according to claim 12, wherein the stripping solution and the workpiece are processed at the same temperature ranging from 35° C. to 45° C. in the removing means.

14. The stripping solution recycling system according to claim 13, wherein the tertiary alkanolamine is N-methyldiethanolamine (MDEA).

15. The stripping solution recycling system according to claim 14, wherein the polar solvent is a mixed solvent of diethylene glycol monobutyl ether and propylene glycol.

16. The stripping solution recycling system according to claim 14, wherein the resist composition is originated from an exposed positive photoresist.

17. The stripping solution recycling system according to claim 14, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

18. The stripping solution recycling system according to claim 15, wherein the resist composition is originated from an exposed positive photoresist.

19. The stripping solution recycling system according to claim 15, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

20. The stripping solution recycling system according to claim 18, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

21. The stripping solution recycling system according to claim 13, wherein the polar solvent is a mixed solvent of diethylene glycol monobutyl ether and propylene glycol.

22. The stripping solution recycling system according to claim 13, wherein the resist composition is originated from an exposed positive photoresist.

23. The stripping solution recycling system according to claim 13, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

24. The stripping solution recycling system according to claim 12, wherein the tertiary alkanolamine is N-methyldiethanolamine (MDEA).

25. The stripping solution recycling system according to claim 12, wherein the polar solvent is a mixed solvent of diethylene glycol monobutyl ether and propylene glycol.

26. The stripping solution recycling system according to claim 12, wherein the resist composition is originated from an exposed positive photoresist.

27. The stripping solution recycling system according to claim 12, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

28. The stripping solution recycling system according to claim 11, wherein the stripping solution and the workpiece are processed at the same temperature ranging from 35° C. to 45° C. in the removing means.

29. The stripping solution recycling system according to claim 28, wherein the tertiary alkanolamine is N-methyldiethanolamine (MDEA).

30. The stripping solution recycling system according to claim 29, wherein the polar solvent is a mixed solvent of diethylene glycol monobutyl ether and propylene glycol.

31. The stripping solution recycling system according to claim 29, wherein the resist composition is originated from an exposed positive photoresist.

32. The stripping solution recycling system according to claim 29, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

33. The stripping solution recycling system according to claim 30, wherein the resist composition is originated from an exposed positive photoresist.

34. The stripping solution recycling system according to claim 30, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

35. The stripping solution recycling system according to claim 33, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

36. The stripping solution recycling system according to claim 28, wherein the polar solvent is a mixed solvent of diethylene glycol monobutyl ether and propylene glycol.

37. The stripping solution recycling system according to claim 28, wherein the resist composition is originated from an exposed positive photoresist.

38. The stripping solution recycling system according to claim 28, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

39. The stripping solution recycling system according to claim 11, comprising a substrate washing line including:
a washing tank for storing the mixed solution supplied through a branch tube branched from the supply line;
a pump for pumping up the mixed solution from the washing tank;
a shower for allowing the mixed solution pumped up by the pump to fall down; and
transfer means for transferring a substrate below the shower.

40. A method for operating the stripping solution recycling system according to claim 11, the method comprising the steps of:
determining a resist concentration of a stripping solution in the stripping solution tank of the resist stripping device;
withdrawing part of the storage stripping solution when the resist concentration reaches a given value;
adding a mixed solution to the stripping solution tank from the supply tank until the resist concentration reaches a given minimum value;
Obtaining a separated liquid containing the main agent and the polar solvent by distilling the withdrawn part of the stripping solution in the distillation and regeneration device;
investigating a component ratio in the separated liquid;
preparing a regenerated mixed solution by adding deficiencies of the main agent, the polar solvent, and water to show a predetermined proportion of the main agent, the polar solvent, and the water in the separated liquid; and
storing the regenerated mixed solution in the supply tank.
